(19) United States
(12) Patent Application Publication
(10) Pub. No.: US 2016/0219998 A1
(43) Pub. Date: Aug. 4, 2016

(54) PROTECTIVE CASE AND ELECTRONIC ASSEMBLY

(71) Applicant: HTC CORPORATION, Taoyuan City (TW)

(72) Inventor: Hung-Chuan Wen, Taoyuan City (TW)

(21) Appl. No.: 14/613,369

(22) Filed: Feb. 4, 2015

(51) Int. Cl. A45C 11/00; H05K 5/00; H05K 5/02

(52) U.S. Cl. CPC A45C 11/00; H05K 5/0217; H05K 5/0086; A45C 2011/002; A45C 2011/003

(57) ABSTRACT

A protective case is suitable for covering a portion of an electronic device. The protective case includes a casing and a band. The casing is adapted to cover the portion of the electronic device and has a first casing joint, a second casing joint and a third casing joint. The band has a first band joint and a second band joint. When the first band joint is temporarily connected to the first casing joint temporarily and the second band joint is temporarily connected to the third casing joint, the band is attached to the case. When the first band joint is temporarily connected to the second casing joint and the second band joint is temporarily connected to the third casing joint, a portion of the band is apart from the casing. An electronic assembly including the above protective case and the above electronic device is also provided here.

### BACKGROUND

1. Technical Field

The application relates to a protective case, and relates particularly to a protective case and an electronic assembly including a protective case.

2. Related Art

Due to designs for miniaturization and diverse functionality, for example, tablet devices such as smart phone, tablet PC and the like are extremely popular amongst consumers. Therefore, related accessories are also developing rapidly. In particular, for example, protective cases and protective covers and the like accessories are the most popular amongst consumers. A protective case typically covers a periphery and a back of a tablet device, and exposes a display, a speaker, a microphones, a camera and the like components of the tablet device to ensure the components operate normally.

### SUMMARY

The application provides a protective case, used to provide a bracelet functionality.

The application provides an electronic assembly, used to provide a bracelet functionality.

The protective case of the application is suitable for covering a portion of an electronic device. The protective case includes a casing and a band. The casing is adapted for covering the portion of the electronic device and has a first casing joint, a second casing joint and a third casing joint. The band has a first band joint and a second band joint. When the first band joint is temporarily connected to the first casing joint and the second band joint is temporarily connected to the third casing joint, the band is attached to the case. When the first band joint is temporarily connected to the second casing joint and the second band joint is temporarily connected to the third casing joint, a portion of the band is apart from the casing.

Based on the above, in the application, the band is apart from the casing may be hanged on objects or hand held by a user according to actual needs, thereby adding additional functionality of the protective case.

To make the above features and advantages of the application more comprehensible, several embodiments accompanied with drawings are described in detail as follows.

### BRIEF DESCRIPTION OF THE DRAWINGS

FIG. 1 is a schematic diagram of an electronic assembly according to an embodiment of the application.

FIG. 2 is an exploded view of a protective case of FIG. 1.

FIG. 3 is a schematic diagram of an end of a band of the protective case of the electronic assembly of FIG. 1 lifted off the casing.

FIG. 4 is a schematic diagram of an end of a band of the protective case of the electronic assembly of FIG. 1 moved to another location of the casing.

FIG. 5 is a schematic diagram of a band of the protective case of the electronic assembly of FIG. 1 acting as a bracelet.

FIG. 6A and FIG. 6B are schematic diagrams of a protective case of FIG. 1 adopting a latching method before and after latching.

FIG. 7 is a partial schematic diagram of the band of the protective case of the electronic assembly of FIG. 1.

FIG. 8A and FIG. 8B are schematic diagrams of a band of FIG. 7 executing settings for an application program corresponding to a tablet device.

### DESCRIPTION OF THE EMBODIMENTS

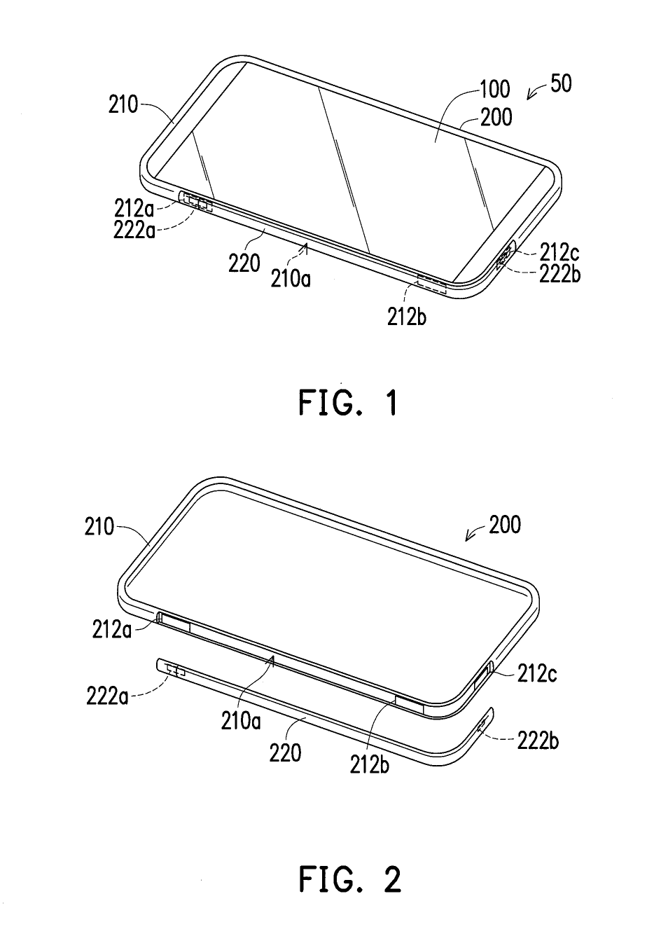

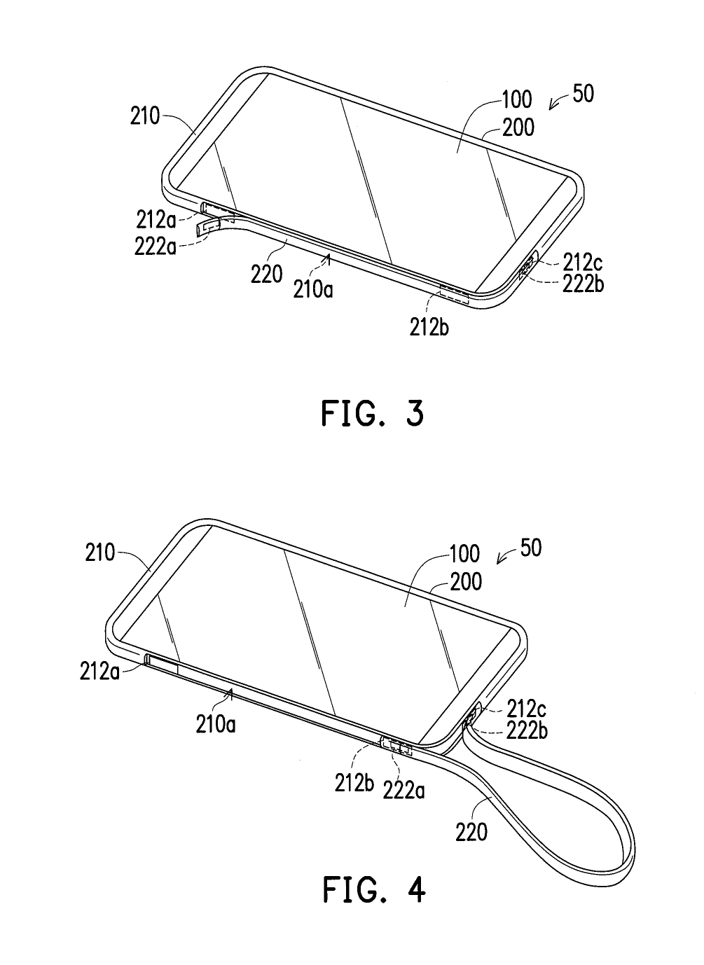

Referring to FIG. 1 and FIG. 2, in the present embodiment, an electronic assembly 50 includes an electronic device 100 and a protective case 200 covering a portion of the electronic device 100. The electronic device 100, for example, is a smart phone, however in other embodiments not shown the electronic device 100 may also be a tablet PC or any electronic device having a display. The protective case 200 includes a casing 210 and a band 220. The band 220 may be temporarily connected to the casing 210, as shown in FIG. 1. In addition, as shown in FIG. 3 and FIG. 4, after being detached from a spot of the casing 210, an end of the band 220 may be temporarily connected again to another spot of the casing 210, such that a portion of the band 220 is apart from the casing 210 allowing the band 220 to become a bracelet connected to the casing 210. In the present embodiment, the casing 210 has a depression 210a, the depression 210a depresses the casing 210 along a periphery of the electronic device 100. When the band 220 is attached on the casing 210, the exterior of the band 220 fits the exterior of the casing 210. In addition, a material of the casing 210 may include rubber or plastic, and a material of the band 220 may include silicon rubber.

Referring to FIG. 2, in the present embodiment, the casing 210 has a first casing joint 212a, a second casing joint 212b and a third casing joint 212c. The band 220 has a first band joint 222a and a second band joint 222b. When the first band joint 222a is temporarily connected to the first casing joint 212a, and the second band joint 222b is temporarily connected to the third casing joint 212c, the band 220 is attached on the casing 210 as shown in FIG. 1. When the first band joint 222a is temporarily connected to the second casing joint 212b, and the second band joint 222b is temporarily connected to the third casing joint 212c, a portion of the band 220 is apart from the casing 210 allowing the band 220 to become a bracelet connected to the casing 210, as shown in FIG. 4. As such, the portion of the band 220 apart from the casing may be hanged on objects or hand held by a user according to actual needs, thereby adding additional functionality of the protective case 200.

Referring to FIG. 2, in the present embodiment, the first casing joint 212a, the second casing joint 212b and the third casing joint 212c are a plurality of magnetic elements, for example, magnetic sensing elements (tin plate, for example), and the first band joint 222a and the second band joint 222b are a plurality of magnetic elements, for example, magnetized elements (permanent magnet, for example). As such, the first band joint 222a may be temporarily connected to the first casing joint 212a or the second casing joint 212b through magnetism, and the second band joint 222b may be temporarily connected to the third casing joint 212c through magnetism.

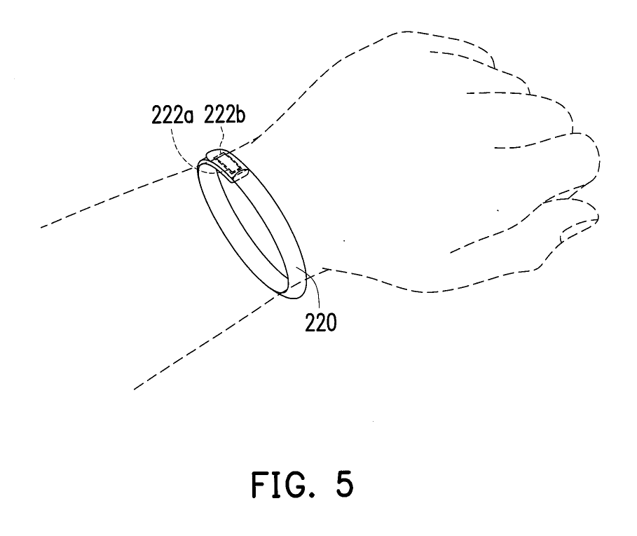

Referring to FIG. 2 and FIG. 5, when the band 220 detaches from the casing 210 and the first band joint 222a is temporarily connected to the second band joint 222b, the band 220 may become a bracelet that may be worn on the wrist of a user or on other parts of the body. Similarly, the first band joint 222a and the second band joint 222b are a plurality of magnetic elements, for example, magnetized elements (permanent magnet, for example), such that the first band joint 222a may be temporarily connected to the second band joint 222b through magnetism.

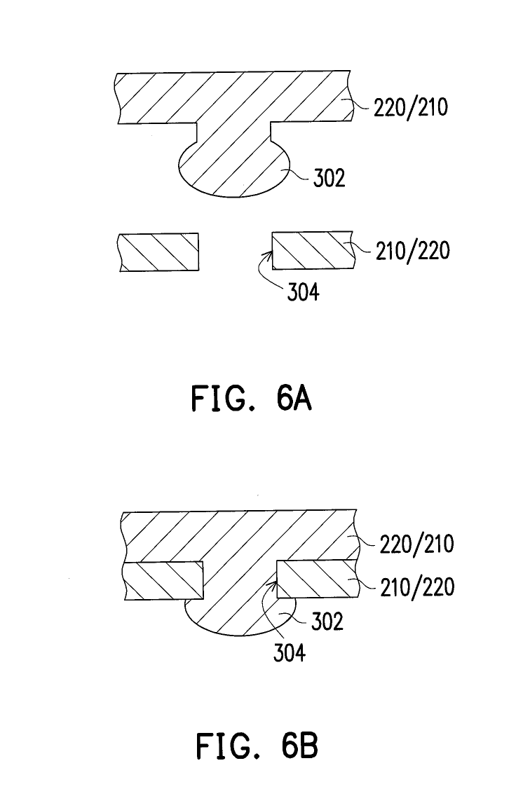

Referring to FIG. 6A and FIG. 6B, aside from adopting magnetic elements for the joints of FIG. 2 (namely the first casing joint 212a, the second casing joint 212b, the second band joint 222b, the first band joint 222a and the second band joint 222b), the joints may also be changed to a plurality of latching elements, a protruding latch part 302 and a latch opening 304 (or dented latch part) respectively to latch together. It should be noted, the band joint 222a and the second band joint 222b of FIG. 2 must be the protruding latch part 302 and the latch opening 304 (or dented latch part) respectively to latch together.

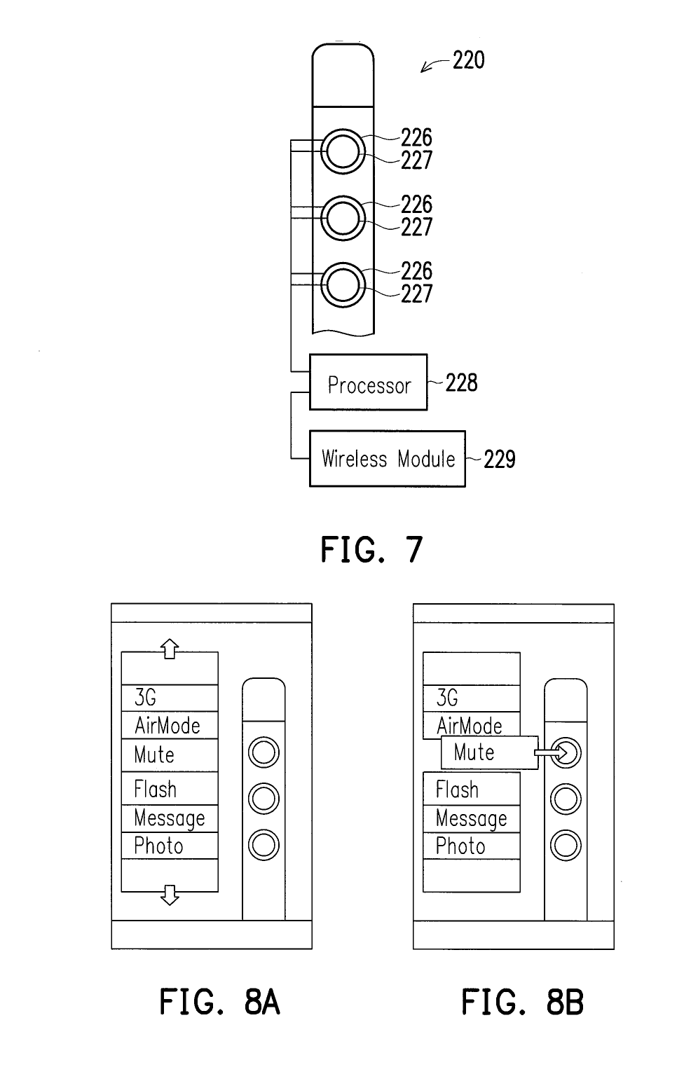

Referring to FIG. 7, in the present embodiment, the band 220 may further have a plurality of indicators 226, a plurality of buttons 227, a processor 228 and a wireless module 229. The indicators 226, the buttons 227 and the wireless module 229 are coupled to the processor 228. The processor 228 receives a signal from the electronic device 100 through the wireless module 229 and drives the indicators 226 in accordance to the signal of the electronic device 100. In addition, the processor 228 produces another signal in accordance to a signal received from the buttons 227 and transmits the another signal to the electronic device 100 through the wireless module 229. Data may be transmitted between the electronic device 100 and the band 220 by a wireless method via the setup. When the electronic device 100 is placed in a user's personal luggage or clothes worn, the user may learn the status of the electronic device 100 through the light produced by the indicators 226 on the band 220 worn on the wrist of the user. And the status of the electronic device 100 may be controlled through pressing the buttons 227 of the band 220.

For example, referring to FIG. 8A and FIG. 8B, a graphical user interface (GUI) of the electronic device 100 may be used to set the uppermost indicator 226 and the uppermost button 227 with functionality that correspond to an incoming call notification and muting of the electronic device 100. As such, when the electronic device 100 receives an incoming call and emits an incoming call sound, the user may learn the electronic device 100 received an incoming call from the uppermost indicator 226 and may turn off the incoming call sound of the electronic device 100 by pressing the uppermost button 227. In other examples, the indicators and the buttons may be set for different functionality, for example, such as turning on or off the flash or for new messages, and it should not be construed as a limitation to the application.

In summary, in the application, a portion of the band apart from a casing may be hanged on objects or hand held by a user according to actual needs, therefore adding additional functionality of the protective case. In addition, when the band has electronic elements (for example, an indicator, a button, a processor, a wireless module), the user may further learn the status of an electronic device by the band and control the status of the electronic device by the band.

Although the application has been described with reference to the above embodiments, the application is not limited to the above embodiments. It is apparent to one of ordinary skill in the art that modifications and variations to the described embodiments may be made without departing from the spirit and scope of the application. Accordingly, the scope of the application will be defined by the attached claims.

What is claimed is:

1. A protective case, suitable for covering a portion of an electronic device, the protective case comprising:
a casing, adapted for covering the portion of the electronic device and having a first casing joint, a second casing joint and a third casing joint; and
a band, having a first band joint and a second band joint, wherein when the first band joint is temporarily connected to the first casing joint and the second band joint is temporarily connected to the third casing joint, the band is attached to the case, and when the first band joint is temporarily connected to the second casing joint and the second band joint is temporarily connected to the third casing joint, a portion of the band is apart from the casing.

2. The protective case as claimed in claim 1, wherein the first band joint is temporarily connected to the first casing joint through magnetism or latching, and the first band joint is temporarily connected to the second casing joint through magnetism or latching.

3. The protective case as claimed in claim 1, wherein the second band joint is temporarily connected to the third casing joint through magnetism or latching.

4. The protective case as claimed in claim 1, wherein when the first band joint is temporarily connected to the second band joint, the band becomes a bracelet.

5. The protective case as claimed in claim 4, wherein the first band joint is temporarily connected to the second band joint through magnetism or latching.

6. The protective case as claimed in claim 1, wherein the casing has a depression, the depression depresses the casing along a periphery of the electronic device, and when the band is attached on the casing, an exterior of the band fits an exterior of the casing.

7. The protective case as claimed in claim 1, wherein the band further has at least one indicator, at least one button, a processor and a wireless module, the at least one indicator, the at least one button and the wireless module are coupled to the processor, the processor receives a signal from the electronic device through the wireless module and drives the indicator in accordance to the signal of the electronic device, and the processor produces another signal in accordance to a signal received from the button and transmits the another signal to the electronic device through the wireless module.

8. An electronic assembly, comprising:
an electronic device; and
a protective case, comprising:
a casing, covering a portion of the electronic device and having a first casing joint, a second casing joint and a third casing joint; and
a band, having a first band joint and a second band joint, wherein when the first band joint is temporarily connected to the first casing joint, and the second band joint is temporarily connected to the third casing joint, the band attaches on the casing, and when the first band joint is temporarily connected to the second casing joint, and the second band joint is temporarily connected to the third casing joint, a portion of the band is apart from the casing.

9. The electronic assembly as claimed in claim 8, wherein the first band joint is temporarily connected to the first casing joint through magnetism or latching, and the first band joint is temporarily connected to the second casing joint through magnetism or latching.

10. The electronic assembly as claimed in claim 8, wherein the second band joint is temporarily connected to the third casing joint through magnetism or latching.

11. The electronic assembly as claimed in claim 8, wherein when the first band joint is temporarily connected to the second band joint, the band becomes a bracelet.

12. The electronic assembly as claimed in claim 11, wherein the first band joint is temporarily connected to the second band joint through magnetism or latching.

13. The electronic assembly as claimed in claim 8, wherein the casing has a depression, the depression is depresses the body along a periphery of the electronic device, and when the band is attached on the casing, an exterior of the band fits an exterior of the casing.

14. The electronic assembly as claimed in claim 8, wherein the band further has at least one indicator, at least one button, a processor and a wireless module, the at least one indicator, the at least one button and the wireless module are coupled to the processor, the processor receives a signal from the electronic device through the wireless module and drives the indicator in accordance to the signal of the electronic device, and the processor produces another signal in accordance to a signal received from the button and transmits the another signal to the electronic device through the wireless module.
